(19) United States
(12) Patent Application Publication
(10) Pub. No.: US 2013/0147486 A1
(43) Pub. Date: Jun. 13, 2013

(54) Power Amplifier Device for a Magnetic Resonance Machine

(71) Applicant: Adam Albrecht, Nuernberg (DE)

(72) Inventor: Adam Albrecht, Nuernberg (DE)

(21) Appl. No.: 13/708,987

(22) Filed: Dec. 8, 2012

(30) Foreign Application Priority Data
Dec. 8, 2011 (DE) DE 102011088028.3

(51) Int. Cl. H05K 7/20; G01R 33/36

(52) U.S. Cl. CPC H05K 7/2089; G01R 33/3614
USPC 324/322; 361/721; 361/717

(57) ABSTRACT

A power amplifier device for a magnetic resonance machine includes a housing, in which a first printed circuit board including at least one amplifier module having at least one power electronics component and at least one conductor pattern connected to the power electronics component is arranged. A second printed circuit board including at least one power electronics component and a conductor pattern is also arranged in the housing. The conductor pattern of the second printed circuit board is connected to at least one connection point of the first printed circuit board in order to supply voltage to the amplifier module. At least one cooling duct for cooling the power electronics components is arranged in the housing. At least two of the power electronics components are arranged such that the electronics components are thermally connected to a common cooling duct on opposite sides of the cooling duct.

This application claims the benefit of DE 10 2011 088 028.3, filed on Dec. 8, 2011, which is hereby incorporated by reference.

### BACKGROUND

The present embodiments relate to a power amplifier device for a magnetic resonance machine.

Magnetic resonance machines, which may be used for clinical imaging applications, are widely known in the prior art. As part of the imaging process in these machines, a transmit antenna is used to excite aligned nuclear spins of a subject under examination, and a receive antenna is used to detect magnetic resonance signals, from which the image data is reconstructed. High powers are used to operate the transmit antenna and are provided by a power amplifier device that may be built into a transmit unit of the magnetic resonance machine.

Power amplifier devices of the prior art may include at least one amplifier module including at least one power electronics component, with as many components and/or conductor patterns as possible being implemented on a common printed circuit board. For example, power amplifier devices that include a plurality of amplifier modules (e.g., four amplifier modules) are known. Each amplifier module of the plurality of amplifier modules may generate an output power of 5 to 8 kW, so that in combination, a power of 30 kW, for example, may be achieved. The amplifier modules, which include an output stage, may therefore also be referred to as output-stage modules. Push-pull output stages that operate on the push-pull principle with symmetrical input signals may be used.

Since the system is working with extremely high powers, the transistors used as the power electronics components in the amplifier modules require cooling. To do this, for example, a copper plate may be arranged beneath the above-mentioned printed circuit board, with coolant ducts running through this plate away from positions to be cooled. The printed circuit board is provided with cut-throughs at the positions intended for the transistors, so that the transistor units provided in a housing may be inserted and brought into direct contact with the copper plate provided beneath the printed circuit board. Other cooling options have also been proposed, however. For example, in the published German patent application DE 10 2011 006 061.8, a substrate structure (e.g., made of ceramic) including integral cooling ducts is used.

Known amplifier modules may operate, for example, in push-pull mode (e.g., as a push-pull output stage), in which a phase of a symmetric input signal is assigned to a respective group of transistors. Each group includes the same number of transistors (e.g., a first group of transistors (which may also include just one transistor) receives a 0° signal, where the other group of transistors (which may contain just one transistor) receives a 180° signal of opposite phase). The drain outputs of the transistor components are brought together in a first conductor pattern that is inductively linked to a second conductor pattern so that the amplified output signal may be produced by inductive coupling.

In addition to the bias voltage, for which the power supply may be implemented on the above-mentioned printed circuit board that also carries the amplifier modules, a high-voltage supply is also provided for amplification and is coupled to the conductor pattern. A separate high-voltage supply (e.g., high-power supply) that is implemented on a further printed circuit board (PCB) is provided for this purpose. The high-voltage supply is connected via suitable cables (e.g., flat cables) to the first printed circuit board that carries the at least one amplifier module, and is coupled from there to the amplifier module (e.g., to the conducting pattern). This creates a long connection path, resulting in disadvantages with regard both to electrical effects and to production. Examples of disadvantages relating to the electrical design are the inductance of the long connection and shielding from electromagnetic interference (EMI). As regards production, there are a very large number of total components that are to be assembled, and therefore, costs are also higher. The power electronic components (e.g., transistors) of the high-voltage supply use a dedicated cooling arrangement or at least a dedicated cooling duct.

### SUMMARY AND DESCRIPTION

The present embodiments may obviate one or more of the drawbacks or limitations in the related art. For example, a more compact power amplifier device that is simple to produce using few parts is provided.

In one embodiment, a power amplifier device for a magnetic resonance machine includes a housing, in which a first printed circuit board including at least one amplifier module containing at least one power electronics component (e.g., a transistor) and at least one conductor pattern connected to the power electronics component is arranged. A second printed circuit board including at least one power electronics component (e.g., a transistor) and a conductor pattern is also arranged in the housing. The power electronics component and the conductor pattern are assigned to a power supply of the amplifier module. The conductor pattern of the second printed circuit board is connected to at least one connection point of the first printed circuit board in order to supply voltage to the amplifier module. At least one cooling duct for cooling the power electronics components is arranged in the housing. At least two power electronics components of the first printed circuit board and the second printed circuit board, which, for example, are arranged in parallel planes, are arranged such that the at least two power electronics are thermally connected to a common cooling duct on opposite sides of the common cooling duct.

A compact design, in which the first printed circuit board and the second printed circuit board are to be provided adjacently such that common cooling ducts may be used for the power electronics components of the first and second printed circuit boards, is provided. The power electronics components of the first printed circuit board and the second printed circuit board are in the form of transistors.

The arrangement is selected such that a cooling duct may be used jointly for at least one pair of power electronics components of the first printed circuit board and the second printed circuit board (e.g., with the power electronics components being arranged such that the power electronics components overlap).

In one embodiment, the high-voltage supply may be implemented close to the first printed circuit board including the at least one amplifier module in a compact arrangement. Thus, shorter connection paths may be provided. The number of parts used for the assembly is also reduced. Therefore, in addition to the space-saving, compact construction, costs may also be saved, since, for example, all the power electronics components of the second printed circuit board are cooled via cooling ducts that are assigned to the power electronics components of the first printed circuit board.

The two printed circuit boards form a type of integral unit, in which the power-supply power electronics components are arranged “above” the cooling ducts that are used by the power electronics components of the amplifier module.

In one embodiment, at least one conductive (e.g., metallized) ground plane of the second printed circuit board forms part of an RF shield for shielding the conductor patterns of the first printed circuit board. The at least one conductive ground plane faces the first printed circuit board. Since RF technology is operating within range of the amplifier modules, shielding is provided. The shielding may be provided according to the prior art as an inner coating of the housing. The embodiment enables at least part of the RF shielding (e.g., part of the RF shield) to be implemented by the second printed circuit board (e.g., by the ground plane lying on the underside thereof and facing the first printed circuit board). Therefore, the high-voltage supply is integrated in the power amplifier device on the shielding plane. By use of further structures that may be metallized or provided with a conductive surface, RF shielding cavities that are, for example, at least partially (e.g., largely) enclosed and facilitate the more compact, more space-saving construction while still providing sufficiently good shielding may be created.

At least one side of the cooling duct and/or at least one side of at least one power electronics component (e.g., of at least one power electronics component of the first printed circuit board) may be provided at least partially with a conductive surface that is connected to the ground plane and forms part of the RF shield. Conductive surfaces that are at ground potential and arranged on the cooling ducts and/or the power electronics components may thus, for example, form a type of “sidewall” of an RF shielding cavity, so that good shielding of the conducting patterns may be realized (e.g., in a portion performing inductive transmission). In addition to the ground plane as a type of “lid”, such “side faces” may form, together with, for example, a ground plane of the first printed circuit board, a cavity that is enclosed at least partially on all sides. A compact design is obtained when, as explained in greater detail below, second printed circuit boards having ground planes are provided on both sides of the first printed circuit board. Each of the second printed circuit boards form part of the RF shield.

If the RF shield is meant to be closed with respect to the outside, then at least part of the RF shield may be formed by a conductive inner surface of the housing (e.g., an inner surface extending between the first printed circuit board and the second printed circuit board). For example, a conductive coating may be provided on the inner surface of the housing between the fixing points of the printed circuit boards to the inner housing in order to close the RF shield with respect to the outside. A fully conductive implementation of the inner surface of the housing is no longer necessary, since the ground plane of the first printed circuit board already provides, at least on one side, a conductive surface as part of the RF shield.

In one embodiment, an at least partially enclosed cavity of the RF shield is formed by conductive surfaces of adjacently arranged power electronics components and of at least one cooling duct, and by the ground plane. Various cavities of the RF shield may be formed in this way according to the position of conductor patterns to be shielded. The cavities are also shielded from one another to a certain degree. Thus, the conductor pattern that actually performs amplification (e.g., amplifying by inductive coupling the signal present at the drain outputs of various transistors) may, for example, be closed on both sides by conductive surfaces of adjacently arranged power electronics components and of at least one cooling duct. For the conductive pattern that provides the incoming lines to the other inputs of the transistors, the side boundary of the cavity is formed by the inner surface of a sidewall of the housing.

The power electronics components of the second printed circuit board may be arranged in a cut-through in the second printed circuit board. This provides that the power electronics components of the second printed circuit board make thermal contact with the cooling duct also from the ground-plane side of the second printed circuit board. Embodiments of this type for connecting such power electronics components to conductor patterns of a printed circuit board are already known in the prior art.

In one embodiment, the first printed circuit board is populated on both sides, and two second printed circuit boards are provided, each on opposite sides of the first printed circuit board. Better use of overall space is thereby achieved by having a type of “sandwich” structure, in which above and below the first printed circuit board, a second printed circuit board is arranged in each case. The second printed circuit boards are assigned to the power supply. For example, a symmetrical design may be provided (e.g., the first printed circuit board may be populated symmetrically, and the second printed circuit boards may be arranged symmetrically). In one embodiment, the ground planes of both second printed circuit boards face the first printed circuit board, so that the ground planes form part of the RF shield on both sides. None of the RF shield needs to be provided on the first printed circuit board itself. Through-holes may be provided for connecting the conductive surfaces provided on both sides of the first printed circuit board, which, for example, may form cavities, as described above.

In one embodiment, the unpackaged power electronics modules are connected at least partially in flip-chip technology. This may be provided for the power electronics components of the first printed circuit board.

In one embodiment, identical power electronics components may be present for the first printed circuit board and for the second printed circuit board. This further simplifies the design and the number of different parts so that symmetrical structures may be implemented advantageously. For example, unpackaged components are suitable as the power electronics components.

In order to produce such a power amplifier device, the power electronics components (e.g., the transistors) may be bonded to both sides of the cooling pipe, which may be implemented, for example, as a copper pipe or a pipe made of metallized plastic that has, for example, a rectangular cross-section. A connection is made to the printed circuit boards (e.g., by flip-chip technology).

In addition to the power amplifier device, a magnetic resonance machine is provided. The magnetic resonance machines includes at least one transmit unit having a power amplifier device. All the embodiments relating to the power amplifier device may also be applied analogously to the magnetic resonance machine, so that the advantages of the specific embodiments are also achieved for the magnetic resonance machine. It is in the field of magnetic resonance machines that compact and space-saving devices may be used advantageously and hence profitably.

### BRIEF DESCRIPTION OF THE DRAWINGS

FIG. 1 shows a schematic diagram of one embodiment of a power amplifier device;

FIG. 2 shows a partial cross-section through one embodiment of the power amplifier device in a region of an amplifier module;

FIG. 3 shows a schematic plan view of one embodiment of a first printed circuit board;

FIG. 4 shows a schematic plan view of one embodiment of a second printed circuit board; and

FIG. 5 shows one embodiment of a magnetic resonance machine.

### DETAILED DESCRIPTION OF THE DRAWINGS

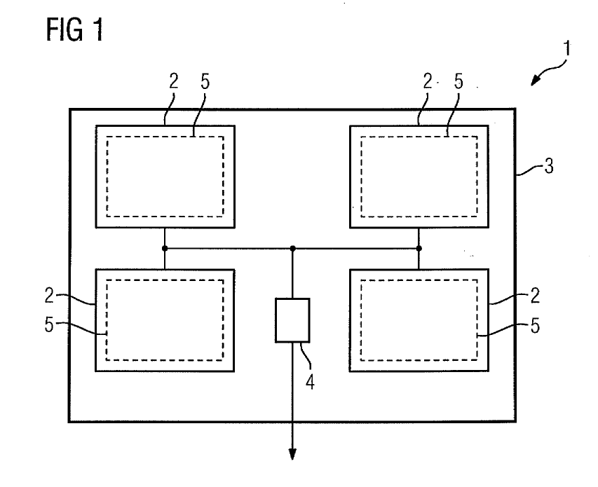

FIG. 1 shows a schematic diagram of one embodiment of a power amplifier device 1. The power amplifier 1 device includes, for example, four power amplifier modules 2 shown schematically in FIG. 1 as function blocks. Each of the four power amplifier modules 2 generates part of the total power and is arranged in a housing 3. The output signals from the amplifier modules 2 are combined into a total output signal (e.g., using a balun 4).

The amplifier modules 2 include, for operation, a power supply 5 that is integrated jointly with the amplifier modules 2 in the housing 3 (e.g., on the shielding level), as is explained in greater detail below.

A number of options for the specific embodiment of the amplifier modules 2 are known in the prior art and are not described in further detail here. For example, output-stage amplifier modules, in which transistors are used as the power electronics components (e.g., sixteen transistors). The drain output signals from the transistors are combined into a total output signal by a conductor pattern. Other embodiments are also possible.

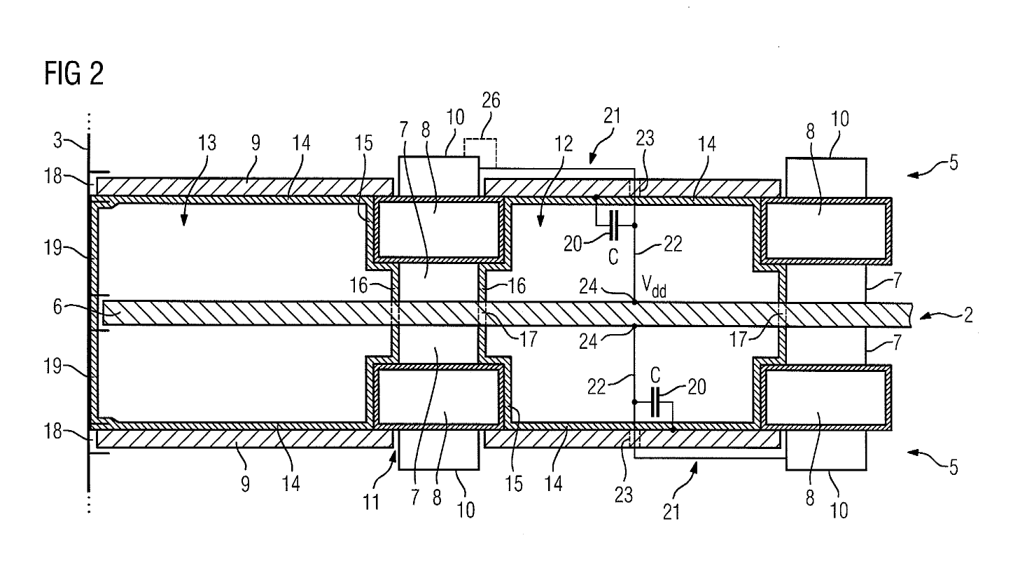

FIG. 2 shows, in greater detail, a partial cross-section through the inside of the power amplifier device 1 in a region of an amplifier module 2. FIG. 2 shows that a first printed circuit board 6, on which the amplifier module 2 including the conductor tracks and transistors 7 is implemented, is provided centrally. The transistors are embodied as transistor components, but FIG. 2 does not show the conductor tracks in greater detail for reasons of clarity. The first printed circuit board 6 is shown populated symmetrically on both sides and may include a plurality of layers, on which conductor tracks are provided.

Since the transistors 7, which include power electronics components, require cooling, at least one cooling duct 8 that may be made of copper, for example, and has a rectangular cross-section is carried in thermal contact with the transistors 7 on an upper side and on the lower side, respectively.

Second printed circuit boards 9, on which the power supply 5 for the amplifier module 2 is implemented, are arranged above and below the first printed circuit board 6. As shown in FIG. 2, the power supply 5 also includes power electronics components in the form of transistors 10 that are arranged in cut-throughs 11 in the second printed circuit board 9, so that the transistors 10 are immediately adjacent to the cooling ducts 8 and may be cooled equally effectively by thermal coupling. This provides that the cooling ducts 8 are used to cool both the transistors 7 and the transistors 10.

As shown in FIG. 2, undersides of the second printed circuit boards 9 are provided with a conductive ground plane 14. The conductive ground plane 14 forms part of an RF shield for the amplifier module 2. The RF shield includes a plurality of RF cavities 12, 13, with an additional contribution also made by the cooling ducts 8 and the transistors 7. Thus, conductive surfaces 15 are initially provided on sides of the cooling ducts 8. The surfaces are connected to the respective ground plane 14 of the second printed circuit boards 9 The transistors 7 also have a conductive coating facing cavities 12, 13 that form a conductive surface 16. A connection between the conductive surfaces lying on the upper side and lower side may be made by suitable through-holes 17.

The cavity 13 is closed on one side by the housing 3, which includes, between relevant retaining devices 18 for the second printed circuit boards 9, a conductive inner surface 19 (e.g., a coating). The conductive inner surface 19, which is connected to the ground plane 14, is configured to run the entire way around (e.g., the conductive inner surface 19 extends along the entire housing between the two second printed circuit boards 9, so that in each case, there is an enclosed, outer boundary to the RF shield).

Thus, the compact construction shown enables not only the use of cooling ducts 8 to cool the transistors 7 and the transistors 10, but also integration of the RF shield in the overall design. The overall design shown also allows a particularly simple connection of a coupling capacitor 20 to ground because, when connecting wires 22 emanating from a conductor pattern 21 provided by the second printed circuit boards 9 are fed through a cut-through 23 to connection points 24 on the first printed circuit board 6, the coupling capacitor 20 may be implemented easily because of the proximity to the ground plane 14.

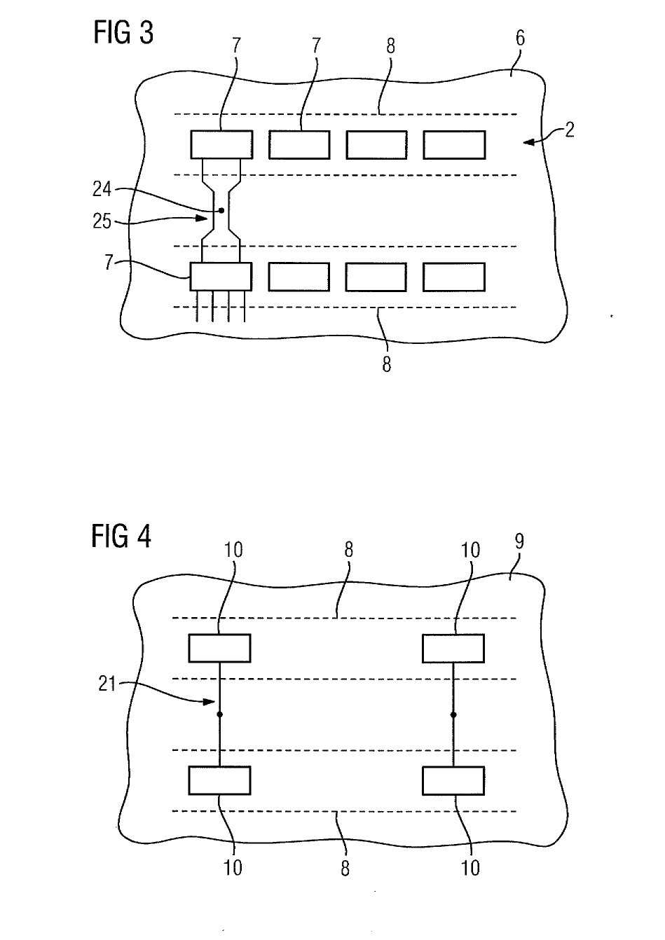

FIG. 3 shows schematically a plan view of one embodiment of the first printed circuit board 6. FIG. 3 shows that for each amplifier module 2 there are eight transistors 7 arranged symmetrically to one another on each side, placed on each side of the printed circuit board 6. Four transistors 7 lie opposite one another on one side. Just an indication of the cooling duct 8 running over the transistors 7 is given in FIG. 3, and likewise for the conductor pattern 25, which is only indicated in part and by way of example for two transistors 7.

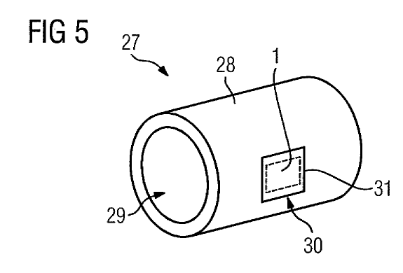

FIG. 4 shows a corresponding plan view of one embodiment of one of the two printed circuit boards 9 from outside. FIG. 4 shows that although only four transistors 10 are used, the four transistors 10 are suitably arranged in the cut-through 11 so that the four transistors 10 lie on the cooling ducts 8 and may also be cooled by the cooling ducts.

A bias-voltage supply for the transistors 7 (not shown in greater detail here) is implemented on the printed circuit board 6, since the bias-voltage supply does not need any additional cooling.

To produce the power amplifier device 1, the transistors 7, 10 may, for example, be thermally bonded to the cooling duct 8 on opposite sides (e.g., using a suitable thermally conductive adhesive). The connection to the first printed circuit board 6 may be made using flip-chip technology, while suitable connection options may be used once the printed circuit boards 9 are in place with, for example, bonding wires 26 also being a possible way of connecting the transistors 10 to the conductor patterns 21, as is shown in FIG. 2, for example.

FIG. 5 shows a schematic diagram of one embodiment of a magnetic resonance machine 27. The magnetic resonance device includes a main magnetic unit 28 that includes a patient receptacle 29 and includes, amongst other elements, coils for generating the main magnetic field. FIG. 5 shows a transmit unit 30 arranged externally on the main magnetic unit 28. The transmit unit 30 includes a housing 31 and one embodiment of the power amplifier device 1.

Other components of the magnetic resonance machine 27 are widely known in the prior art and are not described here in greater detail.

Although the invention has been illustrated and described in greater detail using the exemplary embodiments, the invention is not limited by the disclosed examples, and a person skilled in the art may derive other variations therefrom that are still covered by the scope of protection of the invention.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A power amplifier device for a magnetic resonance machine, the power amplifier device comprising:
a housing;
a first printed circuit board arranged in the housing, the first printed circuit board comprising at least one amplifier module including at least one power electronics component, and at least one conductor pattern connected to the at least one power electronics component;
a second printed circuit board arranged in the housing, the second printed circuit board comprising at least one power electronics component and a conductor pattern, the at least one power electronics component and the conductor pattern being assigned to a power supply of a amplifier module, wherein the conductor pattern of the second printed circuit board is connected to at least one connection point of the first printed circuit board in order to supply voltage to the amplifier module; and
at least one cooling duct arranged in the housing, the at least one cooling duct being operable to cool the power electronics components,
wherein at least two power electronics components of the first printed circuit board and the second printed circuit board, which are arranged in parallel planes, are arranged such that the at least two power electronics components are thermally connected to a common cooling duct on opposite sides of the common cooling duct.

2. The power amplifier device as claimed in claim 1, wherein the at least one power electronics component of the first printed circuit board comprises a transistor.

3. The power amplifier device as claimed in claim 1, wherein the at least one power electronics component of the second printed circuit board comprises a transistor.

4. The power amplifier device as claimed in claim 1, wherein at least one conductive ground plane of the second printed circuit board forms part of an RF shield for shielding the conductor patterns of the first printed circuit board, the at least one conductive ground plane facing the first printed circuit board.

5. The power amplifier device as claimed in claim 4, wherein the at least one conductive ground plane is metalized.

6. The power amplifier device as claimed in claim 4, wherein at least one side of the cooling duct, at least one side of at least one of the power electronics component, or a combination thereof is provided at least partially with a conductive surface that is connected to the ground plane and forms part of the RF shield.

7. The power amplifier device as claimed in claim 4, wherein at least part of the RF shield is formed by a conductive inner surface of the housing.

8. The power amplifier device as claimed in claim 7, wherein the conductive inner surface extends between the first printed circuit board and the second printed circuit board.

9. The power amplifier device as claimed in claim 4, wherein an at least partially enclosed cavity of the RF shield is formed by conductive surfaces of adjacently arranged power electronics components and the common cooling duct, and by the at least one conductive ground plane.

10. The power amplifier device as claimed in claim 4, wherein the at least one power electronics component of the second printed circuit board is arranged in a cut-through in the second printed circuit board.

11. The power amplifier device as claimed in claim 1, wherein the first printed circuit board is populated on both sides, and
wherein the power amplifier device comprises two second printed circuit boards, the two second printed circuit boards comprising the second printed circuit board, the two second printed circuit boards being positioned on opposite sides of the first printed circuit board.

12. The power amplifier device as claimed in claim 1, wherein the power electronics modules are connected at least partially in flip-chip technology.

13. The power amplifier device as claimed in claim 1, wherein identical power electronics components are provided for the first printed circuit board and for the second printed circuit board.

14. A magnetic resonance machine comprising:
at least one transmit unit comprising a power amplifier device, the power amplifier device comprising:
a housing;
a first printed circuit board arranged in the housing, the first printed circuit board comprising at least one amplifier module including at least one power electronics component, and at least one conductor pattern connected to the at least one power electronics component;
a second printed circuit board arranged in the housing, the second printed circuit board comprising at least one power electronics component and a conductor pattern, the at least one power electronics component and the conductor pattern being assigned to a power supply of a amplifier module, wherein the conductor pattern of the second printed circuit board is connected to at least one connection point of the first printed circuit board in order to supply voltage to the amplifier module; and
at least one cooling duct arranged in the housing, the at least one cooling duct being operable to cool the power electronics components,
wherein at least two power electronics components of the first printed circuit board and the second printed circuit board, which are arranged in parallel planes, are arranged such that the at least two power electronics components are thermally connected to a common cooling duct on opposite sides of the common cooling duct.

15. The magnetic resonance machine as claimed in claim 14, wherein the at least one power electronics component of the first printed circuit board comprises a transistor.

16. The magnetic resonance machine as claimed in claim 14, wherein the at least one power electronics component of the second printed circuit board comprises a transistor.

17. The magnetic resonance machine as claimed in claim 14, wherein at least one conductive ground plane of the second printed circuit board forms part of an RF shield for shielding the conductor patterns of the first printed circuit board, the at least one conductive ground plane facing the first printed circuit board.

18. The magnetic resonance machine as claimed in claim 17, wherein the at least one conductive ground plane is metalized.

19. The magnetic resonance machine as claimed in claim 17, wherein at least one side of the cooling duct, at least one side of at least one of the power electronics component, or a combination thereof is provided at least partially with a conductive surface that is connected to the ground plane and forms part of the RF shield.

20. The magnetic resonance machine as claimed in claim 17, wherein at least part of the RF shield is formed by a conductive inner surface of the housing.
